(19) United States
(12) Patent Application Publication
(10) Pub. No.: US 2008/0267279 A1
(43) Pub. Date: Oct. 30, 2008

(54) RFID receiver for miller-encoded signals

(75) Inventor: Yuri Okunev, Middle Island, NY (US)

Correspondence Address: STERNE, KESSLER, GOLDSTEIN & FOX P.L.L.C., 1100 NEW YORK AVENUE, N.W., WASHINGTON, DC, 20005, US

(73) Assignee: Symbol Technologies, Inc., Holtsville, NY (US)

(21) Appl. No.: 11/790,655

(22) Filed: Apr. 26, 2007

(51) Int. Cl. H03K 9/00

(52) U.S. Cl. 375/237

(57) ABSTRACT

A method for decoding a Miller-encoded signal having first and second quadrature components is provided. A Miller sub-carrier signal, synchronized with the Miller-encoded signal, is recovered from the quadrature components. A first, a second, a third, and a fourth half-bit correlation coefficient are calculated from at least one quadrature component and the Miller sub-carrier signal. A cross-correlation result of the first, the second, the third, and the fourth half-bit correlation coefficient is calculated. A value for an output bit is determined from the inverse sign of the cross-correlation result.

### FIELD OF THE INVENTION

The present invention relates to a wireless communication apparatus, system, and method. More specifically, the invention relates to a radio frequency identification (RFID) receiver that detects, demodulates, and decodes a signal from an RFID tag.

### BACKGROUND OF THE INVENTION

A radio frequency identification (RFID) tag is an electronic device that is affixed to an item whose presence is to be detected and/or monitored. The presence of the RFID tag, and thus the presence of the item to which the tag is affixed, is checked and monitored wirelessly by a device known as a “reader.” The reader “interrogates” the tag wirelessly and receives a signal from the tag in response to the interrogation. The reader is sometimes referred to as a “reader interrogator” or an “interrogator.”

In an exemplary RFID system, the reader transmits a continuous wave (CW) or a modulated radio frequency (RF) signal to a tag. The tag receives the signal and responds by modulating the signal via “backscattering” an information signal back to the reader. The reader receives the backscattered signal from the tag. The backscattered signal is demodulated, decoded, and further processed by the reader. A reader may opt to use one of several backscatter encoding methods to encode a transmission such as Miller sub-carrier or FM0. When Miller encoding is used, decoding includes decoding of a Miller-encoded signal having a Miller sub-carrier. The Miller sub-carrier has 2, 4, or 8 sub-carrier cycles in each data symbol. A Miller index (M) describes the number of sub-carrier cycles in each data symbol. In the EPC Generation two standard, a reader specifies the M value in a command transmitted to the tag.

A conventional approach to decoding a Miller-encoded signal consists of computing correlation coefficients between a received signal and a reference signal corresponding to possible transmitted symbols. Therefore, a conventional base-band decoder needs multiple reference signals (data-0 and data-1) and four correlators to decode a Miller-encoded signal. A reference signal frequency that corresponds to data-1 in Miller encoding depends on the Miller Index. Thus, the conventional base-band receiver must generate three different data-1 reference signals (one each for M=2, 4, 8) to accommodate three values of the Miller Index.

In the conventional Miller decoder, generating three different data-1 reference signals requires complicated circuitry, particularly for a high-bit rate RFID system. As a result, conventional decoders are complex, inefficient, expensive, and take up too much space on a semiconductor die.

Thus, there is a need for a high-speed RFID reader that can decode received signals with a plurality of Miller encoding techniques, is simple, inexpensive, reliable, and small.

Further, what is needed is an RFID receiver that overcomes the shortcomings described above.

### BRIEF DESCRIPTION OF THE DRAWINGS/FIGURES

The accompanying drawings illustrate the present invention and, together with the description, further serve to explain the principles of the invention and to enable one skilled in the pertinent art to make and use the invention.

FIG. 1 illustrates an environment where an RFID tag reader communicates with a population of RFID tags.

FIG. 2 illustrates a block diagram of an RFID reader, according to embodiments of the present invention.

FIG. 3 illustrates a method for decoding a Miller-encoded signal from an analog signal, according to embodiments of the present invention.

FIG. 4 illustrates a decoder circuit configured to decode a Miller-encoded signal from an analog signal, according to embodiments of the present invention.

FIG. 5 illustrates a method for decoding a Miller-encoded signal from a digital signal, according to embodiments of the present invention.

FIG. 6 illustrates a decoder circuit configured to decode a Miller-encoded signal from a digital signal, according to embodiments of the present invention.

The invention is described with reference to the accompanying drawings. The drawing in which an element first appears is typically indicated by the leftmost digit(s) in the corresponding reference number.

### DETAILED DESCRIPTION OF THE INVENTION

This specification discloses one or more embodiments that incorporate the features of this invention. The disclosed embodiment(s) merely exemplify the invention. The scope of the invention is not limited to the disclosed embodiment(s). The invention is defined by the claims.

The embodiment(s) described and references in the specification to “one embodiment,” “an embodiment,” “an example embodiment,” etc., indicate that the embodiment(s) described may include a particular feature, structure, or characteristic. However, every embodiment may not necessarily include the particular feature, structure, or characteristic. Moreover, such phrases are not necessarily referring to the same embodiment. When a particular feature, structure, or characteristic is described in connection with an embodiment, it is understood that it is within the knowledge of one skilled in the art to effect such feature, structure, or characteristic in connection with other embodiments, whether or not explicitly described.

### Example RFID System Embodiment

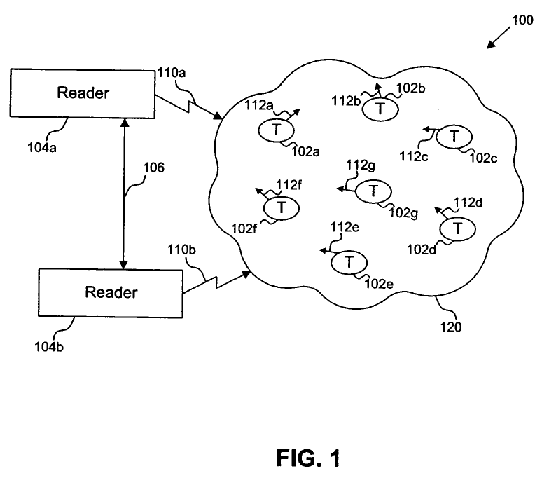

FIG. 1 illustrates an environment 100 where RFID tag readers 104a, 104b communicate with a population 120 of RFID tags 102a, 102b, . . . , 102g. The population 120 may include any number of RFID tags 102. The environment 100 includes at least one reader 104. The reader 104 may be requested by an external device to address the population 120. The reader 104 may have internal logic that initiates communication. The reader 104 may have a trigger mechanism that an operator of the reader 104 uses to initiate communication between the reader 104 and the RFID tag 102. As shown in FIG. 1, the reader 104 transmits an interrogation signal 110a, 110b having a carrier frequency to the population 120. The reader 104 operates in one or more frequency bands. For example, frequency bands of 902-928 MHz and 2400-2483.5 MHz have been defined for certain RFID applications by the Federal Communication Commission (FCC).

Various types of tags 102 may be present in the tag population 120. The RFID tag 102 transmits one or more response signals 112a, 112b, . . . , 112g to the interrogating reader 104 in response to the interrogation signal 110. The response signal 112 may be transmitted by alternatively reflecting and absorbing portions of the interrogation signal 110 according to a time-based pattern. This technique for alternatively absorbing and reflecting the signal 110 is referred to herein as backscatter modulation. A reader may select the backscatter signal encoding method used to encode tag data transmissions. In the Generation two standard, for example, a reader may opt to use a Miller sub-carrier method or an FM0 method. When Miller encoding is used, the response signal 112 contains Miller-encoded data. The reader 104 receives and obtains data from the response signal 112. The data may include an identification number of the responding RFID tag 102 and/or other data stored in the tag 102.

In addition to being capable of communicating with the RFID tags 102, the readers 104 may communicate among themselves in a reader network 106 or with an external server. Each of the readers 104 may transmit a reader signal to another reader 104 via the reader network 106. Further, each of the readers 104 may receive the reader signal from another reader 104.

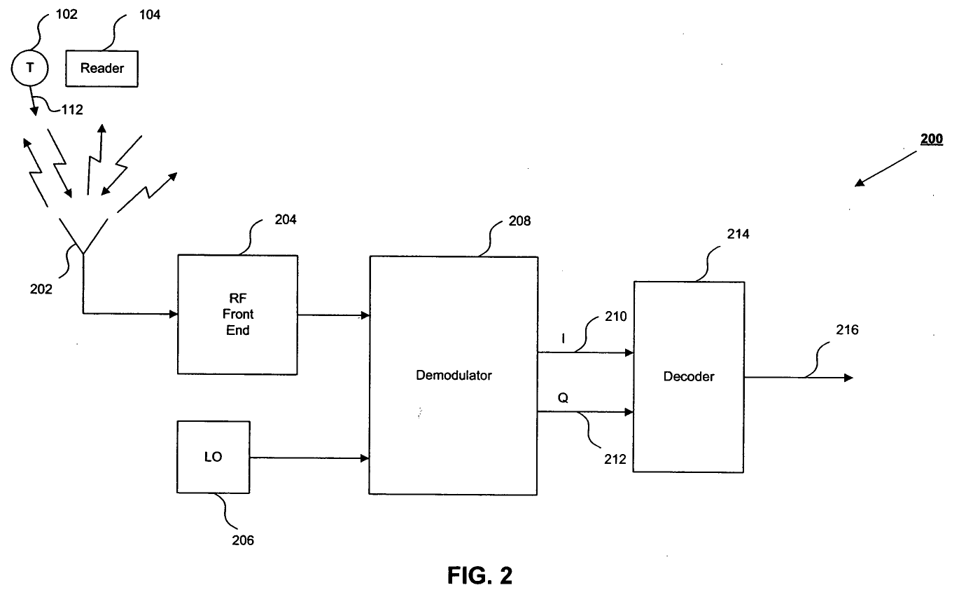

FIG. 2 illustrates a block diagram of an RFID reader 200 according to embodiments of the present invention. The reader 200 includes an antenna 202 for communicating with tags 102 and/or other readers 104 or devices. The antenna 202 receives the response signal 112 and communicates the response signal 112 to a radio frequency (RF) front-end circuit 204. The reader 200 includes a demodulator 208 which linearly transforms a received response signal 112 into base-band quadrature components on a in-phase output (I) 210 and a quadrature output (Q) 212. The output of the demodulator 208 may be analog or digital. The reader 200 also has a decoder 214. The decoder 214 decodes quadrature components of the received modulated Miller carrier signal present on the in-phase output (I) 210 and the quadrature output (Q) 212 into binary data at the decoder output 216. The in-phase output (I) 210 and the quadrature output (Q) 212 may carry a digital quadrature component signal or an analog quadrature component signal. The reader 200 also has a local oscillator (LO) 206 coupled to the demodulator 208.

Method for Decoding a Miller-Encoded Signal from an Analog Signal

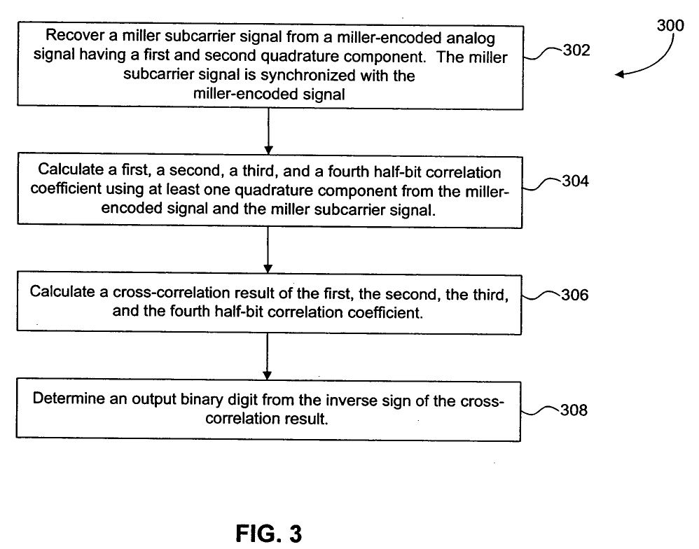

FIG. 3 illustrates a method 300 for decoding a Miller-encoded signal from an analog signal, such as a Miller-encoded signal on the in-phase output (I) 210 and the quadrature output (Q) 212, according to embodiments of the present invention. The method 300 is described with reference to the exemplary reader 200 of FIG. 2. However, the method 300 is not limited to that embodiment. Herein, an in-phase signal (I(t)) and a quadrature signal (Q(t)) represent analog quadrature components of the received modulated carrier received from the in-phase output (I) 210 and the quadrature output (Q) 212 of the I/Q demodulator 208. A Miller sub-carrier synchronized with the I(t) and Q(t) waveforms present on the in-phase output (I) 210 and the quadrature output (Q) 212 is represented by M(t). A symbol interval is represented as [0,T], where T is the symbol duration.

In step 302, a Miller sub-carrier signal (M(t)) is recovered from a Miller-encoded analog signal. Timing information, such as frequency and phase information, is recovered from the Miller-encoded signal and used to determine the Miller sub-carrier signal (M(t)). The Miller sub-carrier signal (M(t)) is synchronized with the Miller-encoded signal.

In step 304, half-bit correlation coefficients are calculated from the Miller-encoded signal. In an embodiment, four half-bit correlation coefficients are calculated. The following equation may be used to determine the first half-bit correlation coefficient (C_{I1}) for the in-phase output (I) 210 over a first half of the symbol duration:

$${C}_{11} = {\int }_{t = 0}^{T / 2} I ( t ) M ( t ) d t$$

Thus, the first half-bit correlation coefficient (C_{I1}) is calculated by integrating a product of the in-phase signal I(t) and the Miller sub-carrier signal M(t) over a first half-bit interval [0,T/2].

The following equation may be used to determine the second half-bit correlation coefficient (C_{I2}) for the in-phase output (I) 210 over a second half of the symbol duration:

$${C}_{12} = {\int }_{t = T / 2}^{T} I ( t ) M ( t ) d t$$

Thus, the second half-bit correlation coefficient (C_{I2}) is calculated by integrating a product of the in-phase signal I(t) and the Miller sub-carrier signal M(t) over a second half-bit interval [T/2, T]. The second half-bit interval is contiguous with the first half-bit interval.

The following equation may be used to determine the third half-bit correlation coefficient (C_{Q1}) for the quadrature output (Q) 212 over the first half of the symbol duration:

$${C}_{Q 1} = {\int }_{t = 0}^{T / 2} Q ( t ) M ( t ) d t$$

Thus, the third half-bit correlation coefficient (C_{Q1}) is calculated by integrating a product of the quadrature signal Q(t) and the Miller sub-carrier signal M(t) over the first half-bit interval [0, T/2].

The following equation may be used to determine the fourth half-bit correlation coefficient (C_{Q2}) for the quadrature output (Q) 212 over the second half of a symbol duration:

$${C}_{Q 2} = {\int }_{t = T / 2}^{T} Q ( t ) M ( t ) d t$$

Thus, the fourth half-bit correlation coefficient (C_{Q2}) is calculated by integrating a product of the quadrature signal Q(t) and the Miller sub-carrier signal M(t) over the second half-bit interval [T/2, T].

In step 306, a cross-correlation result (C_{IQ}) of the correlation coefficients is calculated. For example, when four half-bit correlation coefficients are calculated, the following equation may be used:

C_{IQ}=C_{I1}C_{I2}+C_{Q1}C_{Q2}.

In step 308, an output binary digit, also known as a decision, is determined from an inverse sign of the cross-correlation result:

Decision=−sign(C_{IQ})

In other words, the sign, either positive or negative, of the cross-correlation result (C_{IQ}) is determined. The sign is then inverted to create an inverse sign. Thus, a negative sign is changed to positive and a positive sign is changed to negative. The output binary digit, also known as a value of an output bit, is determined based on the inverse sign. The output binary digit equals a logic high when the inverse sign is positive. The output binary digit equals a logic low when the inverse sign is negative. The output binary digit may be output from the decoder 214 at the decoder output 216. As used herein, the terms “logic bit,” “logic signal,” “binary digit,” and “bit” are used interchangeably to refer to the same signal. Also, the terms “high-level bit,” “logic ‘1’,” “high signal,” and “logic high” are interchangeable. The terms “low-level bit,” logic ‘0’,” and “logic low” are interchangeable.

Circuit for Decoding a Miller-Encoded Signal from an Analog Signal

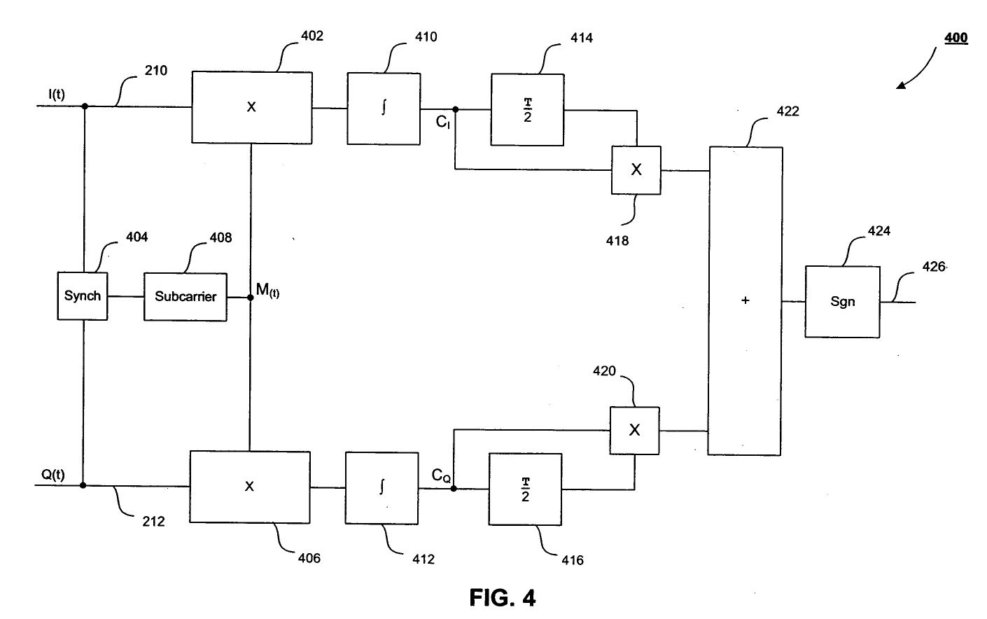

FIG. 4 illustrates an exemplary decoder circuit 400 configured to decode a Miller-encoded signal from an analog signal according to embodiments of the present invention. The decoder circuit 400 may be part of the decoder 214. In an example, to minimize a size of a reader, at least a part of the decoder circuit 400 may be implemented in an integrated circuit having a substrate. Thus, at least a part of the decoder circuit 400 may be deposited on a substrate.

The analog in-phase signal (I(t)) from the demodulator in-phase output (I) is received by a first multiplier 402 and a synchronization circuit 404. The analog quadrature signal (Q(t)) from the demodulator quadrature output (Q) is received by a second multiplier 406 and the synchronization circuit 404. The synchronization circuit 404 recovers timing information, such as frequency and phase information, about the Miller sub-carrier used to encode the in-phase signal (I(t)) and the quadrature signal (Q(t)) from the in-phase signal (I(t)) and the quadrature signal (Q(t)). The synchronization circuit 404 outputs a control signal to a Miller sub-carrier generator 408.

The Miller sub-carrier generator 408 generates the Miller sub-carrier signal (M(t)) that is identical both in frequency and in phase to the Miller sub-carrier used to encode data present in the analog in-phase signal (I(t)) and the analog quadrature signal (Q(t)). The Miller sub-carrier signal is the same for all Miller modes (with Miller index 2, 4, and 8) and depends on a line frequency (LF) according to the standard “Specification for RFID Air Interface—RFID Protocols, Class-1, Generation-2 UHF RFID FlexWorks Air interface Description”, Version 1.0.9, 31 Jan. 2005, herein incorporated by reference in its entirety. Thus, unlike conventional receivers which must generate two or more reference signals, the decoder circuit 400 needs to generate only one reference signal to decode all Miller modes. In the decoder circuit 400, the reference signal is not dependent on the Miller mode. Therefore, the decoder circuit 400 is less complex, more reliable, and less expensive than conventional Miller decoders.

The output of the Miller sub-carrier generator 408 is input to the first multiplier 402 and the second multiplier 406. The first multiplier 402 synchronously multiplies the in-phase signal (I(t)) with the Miller sub-carrier signal (M(t)) to produce an output, substantially equivalent to I(t)M(t), that is input to a first integrator 410. The first integrator 410 integrates the output of the first multiplier 402 over a half-bit interval to produce a first integrator output (C_{I}). The half-bit interval is equal in duration to one-half of a symbol duration (T). The second multiplier 406 synchronously multiplies the analog quadrature signal (Q(t)) with the Miller sub-carrier signal (M(t)) to produce an output, substantially equivalent to Q(t)M(t), that is input to a second integrator 412. The second integrator 412 integrates the output of the second multiplier 406 over the half-bit interval to produce a second integrator output (C_{Q}).

A first delay circuit 414 delays the first integrator output (C_{I}) for a time period equal in duration to one-half of the symbol duration (T). An output of the first delay circuit 414 and the first integrator output (C_{I}) are multiplied by a third multiplier 418. Thus, the decoder circuit 400 performs successive integration. A second delay circuit 416 delays the second integrator output (C_{Q}) for a time period equal in duration to one-half of the symbol duration (T). An output of the second delay circuit 416 and the second integrator output (C_{Q}) are multiplied by a fourth multiplier 420.

Outputs of the third multiplier 418 and the fourth multiplier 420 are added by an adder 422. Thus, an adder output signal is the cross-correlation of the analog in-phase signal (I(t)) and the analog quadrature signal (Q(t)). The adder output signal is coupled to a decision circuit 424. The decision circuit 424 determines a sign, such as positive or negative, of the adder output signal. The determination is made at the end of the symbol duration (T). The sign is uniquely related to the transmitted, Miller-encoded bit. The decision circuit 424 outputs a bit on a decoder output 426. The bit output by the decision circuit 424 is a logic ‘1’ if the sign of the adder output signal is positive, such as “+1.” The bit output by the decision circuit 424 on the decoder output 426 is a logic ‘0’ if the sign of the adder output signal is negative, such as “−1.”

Method for Decoding a Miller-Encoded Signal from a Digital Signal

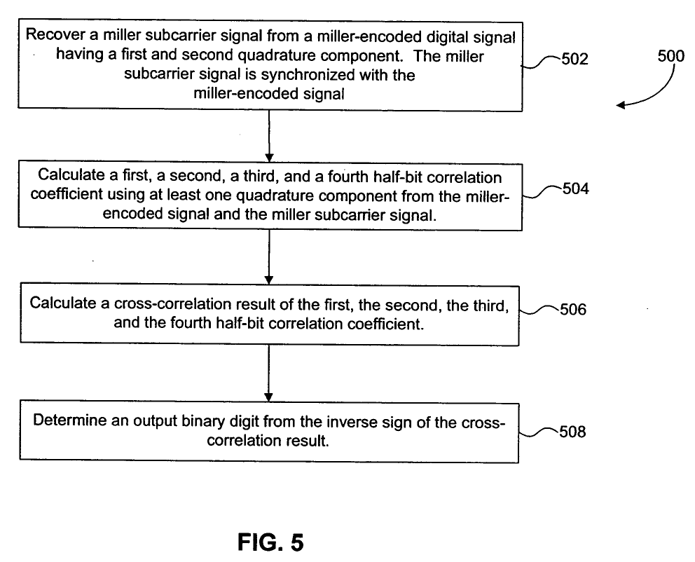

FIG. 5 illustrates a method 500 for decoding a Miller-encoded signal from a digital signal, such as a Miller-encoded signal on the in-phase output (I) 210 and the quadrature output (Q) 212, according to embodiments of the invention. The method 500 is described with reference to the exemplary reader 200. However, the method 500 is not limited to the at embodiment. Herein, an in-phase signal (I(kΔt)) and a quadrature signal (Q(kΔt)) represent k-th sample digital quadrature components, where Δt is a sampling interval. The in-phase signal (I(kΔt)) and the quadrature signal (Q(kΔt)) are received from the in-phase output (I) 210 and the quadrature output (Q) 212 of the I/Q demodulator 208. A k-th sample Miller sub-carrier synchronized with I and Q waveforms present on the in-phase output (I) 210 and the quadrature output (Q) 212 is represented by M(kΔt).

In step 502, a Miller sub-carrier signal (M(kΔt)) is recovered from a Miller-encoded digital signal. Timing information, such as frequency and phase information, is recovered from the Miller-encoded signal and used to determine the Miller sub-carrier signal (M(kΔt)). The Miller sub-carrier signal (M(kΔt)) is synchronized with the Miller-encoded signal.

In step 504, the half-bit correlation coefficients are calculated from the Miller-encoded signal. In an embodiment, four half-bit correlation coefficients are calculated. The following equation may be used to determine the first half-bit correlation coefficient (C_{I1}) for the in-phase signal (I(kΔt)) over a first half of the bit interval:

$${C}_{11} = {\sum }_{k = 1}^{mK / 2} I ( k Δ t ) sgn [ M ( k Δ t ) ]$$

Where mK is an even number of samples within the bit interval. Further, a symbol has K samples within the Miller sub-carrier cycle. The Miller index, that is the number of cycles in the bit interval, is represented by “m” and may be equal to 2, 4, or 8. Thus, the first half-bit correlation coefficient (C_{I1}) is calculated by summing a product of the in-phase signal I(kΔt) and the sign of the Miller sub-carrier signal M(kΔt) over a first half-bit interval [1, mK/2].

The following equation may be used to determine the second half-bit correlation coefficient (C_{I2}) for the in-phase signal (I(kΔt)) over a second half-bit interval:

$${C}_{12} = {\sum }_{k = [ mK / 2 ] + 1}^{mK} I ( k Δ t ) sgn [ M ( k Δ t ) ]$$

Thus, the second half-bit correlation coefficient (C_{I2}) is calculated by summing a product of the in-phase signal I(kΔt) and the sign of the Miller sub-carrier signal M(kΔt) over the second half-bit interval [(mK/2)+1, mK]. The second half-bit interval is contiguous with the first half-bit interval.

The following equation may be used to determine the third half-bit correlation coefficient (C_{Q1}) for the quadrature signal (Q(kΔt)) over the first half-bit interval:

$${C}_{Q 1} = {\sum }_{k = 1}^{mK / 2} Q ( k Δ t ) sgn [ M ( k Δ t ) ]$$

Thus, the third half-bit correlation coefficient (C_{Q1}) is calculated by summing a product of the quadrature signal Q(kΔt) and the sign of the Miller sub-carrier signal M(kΔt) over the first half-bit interval [1, mK/2].

The following equation may be used to determine the fourth half-bit correlation coefficient (C_{Q2}) for the quadrature signal (Q(kΔt)) over the second half-bit interval:

$${C}_{Q 2} = {\sum }_{k = [ mK / 2 ] + 1}^{mK} Q ( k Δ t ) sgn [ M ( k Δ t ) ]$$

Thus, the fourth half-bit correlation coefficient (C_{Q2}) is calculated by summing a product of the quadrature signal Q(kΔt) and the sign of the Miller sub-carrier signal M(kΔt) over the second half-bit interval [(mK/2)+1, in K].

In step 506, a cross-correlation result (C_{IQ}) of the correlation coefficients is calculated. For example, when four half-bit correlation coefficients are calculated, the following equation may be used:

C_{IQ}=C_{I1}C_{I2}+C_{Q1}C_{Q2}.

In step 508, an output binary digit, is determined from an inverse sign of the cross-correlation result (C_{IQ}):

Decision=−sign(C_{IQ})

Thus, the sign, either positive or negative, of the cross-correlation result (C_{IQ}) is determined. The sign is then inverted to create an inverse sign. Thus, a negative sign is changed to positive and a positive sign is changed to negative. The output binary digit is determined based on the inverse sign. The output binary digit equals a logic high when the inverse sign is positive. The output binary digit equals a logic low when the inverse sign is negative. The output binary digit may be output from the decoder 214 at the decoder output 216.

Circuit for Decoding a Miller-Encoded Signal from a Digital Signal

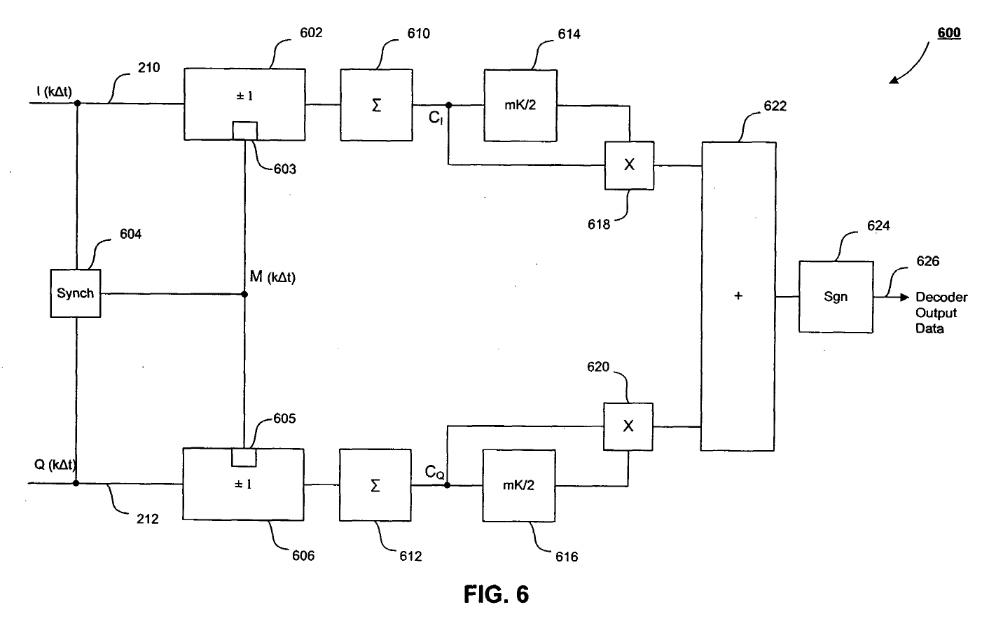

FIG. 6 illustrates a decoder circuit 600 configured to decode a Miller-encoded signal from a digital signal according embodiments of the present invention. The decoder circuit 600 may be part of the decoder 214. In an example, to minimize a size of a reader, the decoder circuit 400 may be implemented in an integrated circuit having a substrate. Thus, at least a part of the decoder circuit 600 may be deposited on a substrate.

A digital in-phase signal (I(kΔt)) from a demodulator in-phase output (I) is received by a first controlled inverter 602 and a synchronization circuit 604. A digital quadrature signal (Q(kΔt)) from a demodulator quadrature output (Q) is received by a second controlled inverter 606 and the synchronization circuit 604. The synchronization circuit 604 recovers timing information, such as frequency and phase information, about the Miller sub-carrier used to encode the in-phase signal (I(kΔt)) and the quadrature signal (Q(kΔt)). The synchronization circuit 604 recovers the timing information from the in-phase signal (I(kΔt)) and the quadrature signal (Q(kΔt)). The synchronization circuit 604 outputs the Miller sub-carrier signal (M(kΔt)) that is identical, both in frequency and in phase, to the Miller sub-carrier used to encode data present in the digital in-phase signal (I(kΔt)) and the digital quadrature signal (Q(kΔt)). The Miller sub-carrier signal is the same for all Miller modes (with Miller index 2, 4, and 8) and depends on the line frequency (LF). Unlike conventional receivers which use two or more reference signals, the decoder circuit 400 needs to generate only one reference signal to decode all Miller modes. The reference signal is not dependent on the Miller mode. Therefore, the decoder circuit 600 is less complex, more reliable, and less expensive than conventional Miller decoders.

The output of the synchronization circuit 604 is input to a control input 603 of the first controlled inverter 602. The output of the synchronization circuit 604 is also input to a control input 605 of the second controlled inverter 606. The first controlled inverter 602 synchronously changes sample signs of the digital in-phase signal (I(kΔt)) with a period corresponding to the line frequency (LF), i.e. according to function sgn[M(kΔt)], to produce output samples, equivalent to I(kΔt)sgn[M(kΔt)], that are input to a first adder-accumulator 610. The first adder-accumulator 610 sums the output samples of the first controlled inverter 602 over a half-bit interval to produce a first adder-accumulator output (C_{I}). The half-bit interval is equal to half of the number of samples within the sub-carrier cycle multiplied by the Miller index.

The second controlled inverter 606 synchronously changes sample signs of the digital quadrature signal (Q(kΔt)) with a period corresponding to the line frequency (LF) to produce output samples, equivalent to Q(kΔt)sgn[M(kΔt)], that are input to a second adder-accumulator 612. The second adder-accumulator 612 sums the output samples of the second controlled inverter 606 over a half-bit interval to produce a second adder-accumulator output (C_{Q}).

The adder-accumulators 610, 612 sum the input samples during two half-bit intervals from K=1 to k=mK/2 and from k=(mk/2)+1 to k=mK. The interval of summation may be provided by the symbol synchronization block. A first delay circuit 614, such as a digital memory circuit, delays the first adder-accumulator output (C_{I}) for a half-bit interval. An output of the first delay circuit 614 and the first adder-accumulator output (C_{I}) are multiplied by a first multiplier 618. Thus, the decoder circuit 600 performs successive summation. A second delay circuit 616, such as a digital memory circuit, delays the second adder-accumulator output (C_{Q}) for a half-bit interval. An output of the second delay circuit 616 and the second adder-accumulator output (C_{Q}) are multiplied by a second multiplier 620.

Outputs of the first multiplier 618 and the second multiplier 620 are added by an adder 622. Thus, an output signal of the adder 622 is the cross-correlation of the digital in-phase signal (I(kΔt)) and the digital quadrature signal (Q(kΔt)). The adder output signal is coupled to a decision circuit 624. The decision circuit 624 determines a sign, such as positive or negative, of the adder output signal. The determination is made at the end of the bit interval. The sign is uniquely related to the transmitted, Miller-encoded bit. The decision circuit 624 outputs a bit on a decoder output 626. The bit output by the decision circuit 624 is a logic ‘1’ if the sign of the adder output signal is positive, such as “+1.” The bit output by the decision circuit 624 on the decoder output 626 is a logic ‘O’ if the sign of the adder output signal is negative, such as “−1.”

### CONCLUSION

While various embodiments of the present invention have been described above, it should be understood that they have been presented by way of example and not limitation. It will be apparent to one skilled in the pertinent art that various changes in form and detail can be made therein without departing from the spirit and scope of the invention. Therefore, the present invention should only be defined in accordance with the following claims and their equivalents.

What is claimed is:

1. A method for decoding a miller-encoded signal, comprising:
recovering a miller sub-carrier signal from the miller-encoded signal having a first and second quadrature component;
wherein the miller sub-carrier signal is synchronized with the miller-encoded signal;
calculating a first, a second, a third, and a fourth half-bit correlation coefficient using at least one quadrature component from the miller-encoded signal and the miller sub-carrier signal;
calculating a cross-correlation result using the first, the second, the third, and the fourth half-bit correlation coefficient; and
determining a value for an output bit as the inverse sign of the cross-correlation result.

2. The method of claim 1, wherein the calculating further comprises:
wherein the first quadrature component is an in-phase signal and the second quadrature component is a quadrature signal;
calculating the first half-bit correlation coefficient by integrating a product of the in-phase signal and the miller sub-carrier signal over a first half-bit interval;
calculating the second half-bit correlation coefficient by integrating a product of the in-phase signal and the miller sub-carrier signal over a second half-bit interval;
calculating the third half-bit correlation coefficient by integrating a product of the quadrature signal and the miller sub-carrier signal over the first half-bit interval; and
calculating the fourth half-bit correlation coefficient by integrating a product of the quadrature signal and the miller sub-carrier signal over the second half-bit interval.

3. The method of claim 2, wherein the second half-bit interval is contiguous with the first half-bit interval.

4. The method of claim 1, wherein the calculating further comprises:
wherein the first quadrature component is an in-phase signal and the second quadrature component is a quadrature signal;
calculating the first half-bit correlation coefficient by summing a product of the in-phase signal during a first sample interval with a sign of a synchronized miller sub-carrier signal during the first sample interval, wherein the summing is performed over a first half-bit interval;
calculating the second half-bit correlation coefficient by summing a product of the in-phase signal during a second sample interval with a sign of the synchronized miller sub-carrier signal during the second sample interval, wherein the summing is performed over a second half-bit interval;
calculating the third half-bit correlation coefficient by summing a product of the quadrature signal during the first sample interval with the sign of the synchronized miller sub-carrier signal during the first sample interval, wherein the summing is performed over the first half-bit interval; and
calculating the fourth half-bit correlation coefficient by summing a product of the quadrature signal during the second sample interval with the sign of the synchronized miller sub-carrier signal during the second sample interval, wherein the summing is performed over the second half-bit interval.

5. The method of claim 4, wherein the second half-bit interval is contiguous with the first half-bit interval.

6. The method of claim 1, wherein the calculating further comprises:
multiplying the first and the second half-bit correlation coefficients to create a first product;
multiplying the third and the fourth half-bit correlation coefficients to create a second product; and
adding the first and the second products to generate the cross-correlation result.

7. The method of claim 1, wherein the value of the output bit equals a logic high when the inverse sign is positive.

8. The method of claim 1, wherein the value of the output bit equals a logic low when the inverse sign is negative.

9. The method of claim 1, further comprising receiving the miller-encoded signal from a radio-frequency identification (RFID) tag.

10. A decoder circuit configured to decode a miller-encoded signal having a first and a second quadrature component, comprising:
means for calculating a first, a second, a third, and a fourth half-bit correlation coefficient using at least one quadrature component from the miller-encoded signal and a reference miller sub-carrier signal;
means for calculating a cross-correlation result using the first, second, third, and fourth half-bit correlation coefficients; and
means for determining a value of an output bit as the inverse sign of the cross-correlation result.

11. The decoder circuit of claim 10, wherein the calculating means further comprises:
wherein the first quadrature component is an in-phase signal and the second quadrature component is a quadrature signal;
means for calculating the first half-bit correlation coefficient by integrating a product of the in-phase signal and a synchronized miller sub-carrier signal over a first half-bit interval;
means for calculating the second half-bit correlation coefficient by integrating a product of the in-phase signal and the synchronized miller sub-carrier signal over a second half-bit interval;
means for calculating the third half-bit correlation coefficient by integrating a product of the quadrature signal and the synchronized miller sub-carrier signal over the first half-bit interval; and
means for calculating the fourth half-bit correlation coefficient by integrating a product of the quadrature signal and the synchronized miller sub-carrier signal over the second half-bit interval.

12. The decoder circuit of claim 11, wherein the second half-bit interval is contiguous with the first half-bit interval.

13. The decoder circuit of claim 10, wherein the calculating means further comprises:
means for multiplying the first and the second half-bit correlation coefficients to create a first product;
means for multiplying the third and the fourth half-bit correlation coefficients to create a second product; and
means for adding the first and the second products to generate the cross-correlation result.

14. The decoder circuit of claim 10, wherein the value of the output bit equals a logic high when the inverse sign is positive.

15. The decoder circuit of claim 10, wherein the value of the output bit equals a logic low when the inverse sign is negative.

16. The decoder circuit of claim 10, further comprising means for receiving the miller-encoded signal from a radio-frequency identification (RFID) tag.

17. A decoder circuit configured to decode Miller-encoded signals having an in-phase component and a quadrature component, comprising:
a first multiplier including:
an input for receiving the in-phase component of the miller-encoded signal;
a second input; and
an output;
a second multiplier including:
an input for receiving the quadrature component of the miller-encoded signal;
a second input; and
an output;
a synchronization circuit coupled to the first multiplier and the second multiplier;
a sub-carrier generator coupled to the synchronization circuit, the first multiplier, and the second multiplier, wherein the sub-carrier generator is configured to provide a reference Miller sub-carrier signal to the second input of the first multiplier and the second input of the second multiplier;
a first integrator coupled to the first multiplier;
a second integrator coupled to the second multiplier;
a cross-correlation circuit coupled to the first and second integrators; and
a decision circuit coupled to the cross-correlation circuit.

18. The decoder circuit of claim 17, wherein the cross-correlation circuit includes:
a first delay line having an output and coupled to the first integrator;
a second delay line having an output and coupled to the second integrator;
a third multiplier including:
a first input coupled to the first delay line output;
a second input coupled to the first integrator, and
an output;
a fourth multiplier including:
a first input coupled to the second delay line output;
a second input coupled to the second integrator, and
an output; and
an adder including:
a first input coupled to the third multiplier output;
a second input coupled to the fourth multiplier output; and
an output coupled to the decision circuit.

19. The decoder circuit of claim 17, wherein at least a part of the decoder circuit is deposited on a substrate.

20. The decoder circuit of claim 17, wherein at least a part of the decoder circuit is part of a receiver.

21. The decoder circuit of claim 20, wherein at least a part of the decoder circuit is part of a radio frequency identification (RFID) reader.

22. A digital decoder circuit configured to decode a miller-encoded signal having an in-phase component and a quadrature component, comprising:
a first controlled inverter including:
an input for receiving the in-phase component of the Miller-encoded signal;
a control input; and
an output;
a second controlled inverter including:
an input for receiving the quadrature component of the Miller-encoded signal;
a control input; and
an output;
a synchronization circuit including:
a first input coupled to the first controlled inverter input;
a second input coupled to the second controlled inverter input; and
an output coupled to both the first inverter control input and the second inverter control input;
wherein the synchronization circuit is configured to provide a reference Miller sub-carrier signal to the control inputs of the first and second controlled inverters;
a first summation circuit coupled to the first controlled inverter;
a second summation circuit coupled to the second controlled inverter;
a cross-correlation circuit coupled to the first and second summation circuits; and
a decision circuit coupled to the cross-correlation circuit.

23. The digital decoder circuit of claim 22, wherein the cross-correlation circuit includes:
a first delay circuit including:
an output; and
an input coupled to the first summation circuit;
a second delay circuit including:
an output; and
an input coupled to the second summation circuit;
a first multiplier including:
a first input coupled to the first delay circuit output;
a second input coupled to the first summation circuit, and
an output;
a second multiplier including:
a first input coupled to the second delay circuit output;
a second input coupled to the second summation circuit, and
an output; and
an adder including:
a first input coupled to the first multiplier output;
a second input coupled to the second multiplier output; and
an output coupled to the decision circuit.

24. The digital decoder circuit of claim 22, wherein at least a part of the decoder circuit is deposited on a substrate.

25. The digital decoder circuit of claim 22, wherein at least a part of the decoder circuit is part of a receiver.

26. The digital decoder circuit of claim 25, wherein at least a part of the decoder circuit is part of a radio frequency identification (RFID) reader.
